(19) United States
(12) Patent Application Publication
(10) Pub. No.: US 2024/0234187 A1
(43) Pub. Date: Jul. 11, 2024

(54) SUBSTRATE SUPPORTER, SUBSTRATE PROCESSING APPARATUS, METHOD OF MEASURING TEMPERATURE, METHOD OF MANUFACTURING SEMICONDUCTOR DEVICE AND RECORDING MEDIUM

(71) Applicant: Kokusai Electric Corporation, Tokyo (JP)

(72) Inventors: Hitoshi MURATA, Toyama-shi (JP); Takayuki Nakada, Toyama-shi (JP); Masaaki Ueno, Toyama-shi (JP)

(73) Assignee: Kokusai Electric Corporation, Tokyo (JP)

(21) Appl. No.: 18/611,232

(22) Filed: Mar. 20, 2024

Related U.S. Application Data
(63) Continuation of application No. PCT/JP21/35555, filed on Sep. 28, 2021.

(51) Int. Cl. H01L 21/67; H01L 21/66; H01L 21/673

(52) U.S. Cl. CPC H01L 21/67248; H01L 21/6732; H01L 22/12

(57) ABSTRACT

Provided is a technique including a plurality of supports configured to support a substrate; at least one upright including a first space inside; and a temperature sensor provided in the first space, the temperature sensor including a temperature detector configured to measure a temperature of the substrate, in which at least one support of the plurality of supports includes a second space inside in communication with the first space to allow the temperature detector to be installed in the second space.

### CROSS-REFERENCE TO RELATED APPLICATIONS

This application is a Bypass Continuation Application of PCT International Application No. PCT/JP2021/035555, filed on Sep. 28, 2021, the entire contents of which are incorporated herein by reference.

### BACKGROUND

### Field

The present disclosure relates to a substrate supporter, a substrate processing apparatus, a method of measuring temperature, a method of manufacturing a semiconductor device and a recording medium.

### Description of the Related Art

In some cases, as a partial process in a process of manufacturing a semiconductor device, the processing of forming a film on a substrate is performed. In such cases, in order to measure the temperature of the substrate accurately in processing the substrate, a temperature sensor requires locating close to the substrate.

### SUMMARY

Some embodiments of the present disclosure provide a technique enabling a temperature sensor to be close to a substrate in processing the substrate.

According to an aspect of the present disclosure,
provided is a technique including: a plurality of supports each configured to support a substrate; at least one upright including a first space inside; and a temperature sensor provided in the first space, the temperature sensor including a temperature detector configured to measure a temperature of the substrate, in which at least one support of the plurality of supports includes a second space inside in communication with the first space to allow the temperature detector to be installed in the second space.

### BRIEF DESCRIPTION OF THE DRAWINGS

FIG. 1 is a front sectional view of a substrate processing apparatus according to an embodiment of the present disclosure.

FIG. 2 illustrates a schematic configuration of the substrate processing apparatus according to the embodiment of the present disclosure.

FIG. 3 illustrates a hardware configuration of a controller in the substrate processing apparatus according to the embodiment of the present disclosure.

FIG. 4 illustrates a heater drive for a heater unit and control thereof, according to the embodiment of the present disclosure.

FIG. 5 is a graph indicating the temperature difference between the temperature measured by a thermocouple of a thermocouple-equipped substrate and the temperature measured by a temperature sensor disposed close to the thermocouple-equipped substrate.

FIG. 6 explanatorily illustrates a measurement method for the measurements indicated in FIG. 5.

FIG. 7 illustrates a schematic configuration of the substrate processing apparatus according to the embodiment of the present disclosure.

FIG. 8A is a longitudinal sectional view illustrating a schematic configuration of a boat assembly according to the embodiment of the present disclosure and illustrates a temperature detector out of contact with the inner wall of a support. FIG. 8B is a longitudinal sectional view illustrating a schematic configuration of the boat assembly according to the embodiment of the present disclosure and illustrates the temperature detector in contact with the inner wall of the support.

FIG. 9 is a longitudinal sectional view illustrating a location near the temperature sensor of the boat assembly according to the embodiment of the present disclosure.

FIG. 10 is a flowchart of a process of substrate processing according to the embodiment of the present disclosure.

### DETAILED DESCRIPTION

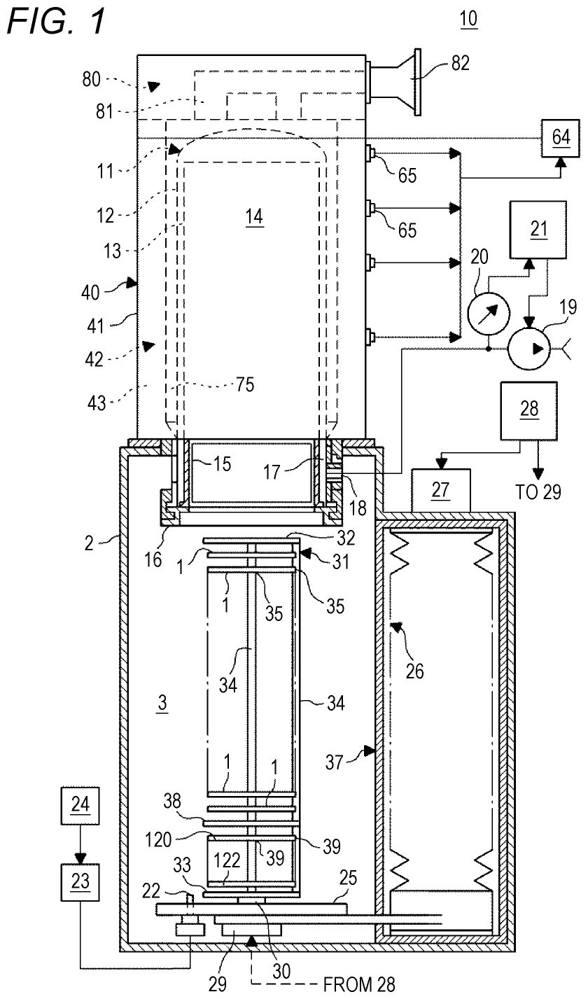

An aspect of the present disclosure will be described below mainly with reference to FIGS. 1 to 10. Note that the drawings used in the following description are all schematic and thus, for example, the dimensional relationship between each constituent element and the ratio between each constituent element illustrated in the drawings do not necessarily coincide with realities. In addition, for example, a plurality of drawings does not necessarily coincide with each other in the dimensional relationship between each constituent element or in the ratio between each constituent element.

### (1) Configuration of Substrate Processing Apparatus

A substrate processing apparatus 10 illustrated in FIG. 1 includes a process tube 11 serving as a supported upright reaction tube. The process tube 11 includes an outer tube 12 and an inner tube 13 disposed concentrically. The outer tube 12 is molded as one item from quartz (SiO₂) and is cylindrical in shape with an upper end occluded and a lower end open. The inner tube 13 is cylindrical in shape with an upper end open and a lower end open. The inner tube 13 has a tubular hollow forming a process chamber 14 into which a boat 31 is loaded. The inner tube 13 has, on its lower end side (at its opening space), a furnace opening 15 for loading or unloading the boat 31. As described later, the boat 31 retains a plurality of substrates (hereinafter, also referred to as wafers) 1 arrayed lengthwise. Therefore, the inner diameter of the inner tube 13 is set larger than the maximum outer diameter of a substrate 1 to be treated (e.g., a diameter of 300 mm).

The lower end portion between the outer tube 12 and the inner tube 13 is airtightly sealed by a manifold 16 serving as a furnace-opening flange substantially cylindrical in shape. For example, for replacement of the outer tube 12 and the inner tube 13, the manifold 16 is detachably attached to each of the outer tube 12 and the inner tube 13. The manifold 16 is supported by a casing 2 of the substrate processing apparatus 10, so that the process tube 11 is installed vertically. Hereinafter, in some drawings, the inner tube 13 of the process tube 11 is omitted.

Due to the gap between the outer tube 12 and the inner tube 13, in cross sectional view, an exhaust path 17 is shaped like a circular ring including a constant width. As illustrated in FIG. 1, the manifold 16 has a side wall including its upper portion to which an end of an exhaust pipe 18 is connected, so that the exhaust pipe 18 is in communication with the lowermost end portion of the exhaust path 17. The exhaust pipe 18 has its other end to which an exhaust 19, which is controlled by a pressure controller 21, is connected, and has a pressure sensor 20 connected thereto between the end and the other end. Based on a measurement result from the pressure sensor 20, the pressure controller 21 feedback-controls the exhaust 19.

A gas introducing pipe 22 is disposed, for communication with the furnace opening 15 of the inner tube 13, below the manifold 16. A source gas supplier, a reactant gas supplier, and an inert gas supplier (hereinafter, referred to as a gas supplier) 23 are connected to the gas introducing pipe 22. A gas flow rate controller 24 controls the gas supplier 23. The gas introduced from the gas introducing pipe 22 to the furnace opening 15 flows through the process chamber 14 of the inner tube 13. Then, the gas passes through the exhaust path 17 and then is exhausted through the exhaust pipe 18.

In order to occlude the opening at the lower end of the manifold 16, a seal cap 25 comes contact with the manifold 16 vertically from below. The seal cap 25 is discoid in shape and has a diameter substantially equal to the outer diameter of the manifold 16. A boat elevator 26, which is installed in a transfer chamber 3 of the casing 2 and is protected with a boat cover 37, raises/lowers the seal cap 25 vertically. The boat elevator 26 includes, for example, a motor-driven screw feeder and a bellows. A drive controller 28 controls a motor 27 for the boat elevator 26. A rotary shaft 30 is disposed on the central line of the seal cap 25 and is supported rotatably. A motor 29 controlled by the drive controller 28 drives the rotary shaft 30 to rotate. The rotary shaft 30 has an upper end at which the boat 31 is supported vertically. In the present embodiment, a rotator is achieved with the rotary shaft 30 and the motor 29. The rotator rotates the boat 31 such that the substrates 1 rotate along with the rotation of the boat 31.

The boat 31 serving as a substrate supporter includes end plates 32 and 33 paired in its up-down direction and three props (poles) 34 serving as three uprights ranging vertically between the end plates 32 and 33. The three props 34 are each provided with a plurality of supports 35 at regular intervals (at regular pitch widths) in its longitudinal direction (in the direction parallel to the props 34). The respective supports 35 of the three props 34 at each level between the three props 34 protrude and face mutually. A substrate 1 is inserted between the respective supports 35 that the three props 34 have at each level between the three props 34, so that the boat 31 retains a plurality of substrates 1 arrayed, the plurality of substrates 1 remaining horizontal and including the respective centers identical. A heat insulating plate 120 is inserted between the respective supports 39 that the three props 34 have at each level between the three props 34, so that the boat 31 retains a plurality of heat insulating plates 120 arrayed, the plurality of heat insulating plates 120 remaining horizontal and including the respective centers identical. Note that the pitch width between substrates 1 and the pitch width between heat insulating plates 120 may be different from each other.

That is, the boat 31 has separately a substrate processing region in which the plurality of substrates 1 is retained between the end plate 32 and an end plate 38 and a heat-insulating-plate region in which the plurality of heat insulating plates 120 is retained between the end plate 38 and the end plate 33. The heat-insulating-plate region is disposed below the substrate processing region. A heat insulator 36 is achieved with the heat insulating plates 120 retained between the end plate 38 and the end plate 33.

The rotary shaft 30 supports the boat 31 such that the boat 31 is located above the upper face of the seal cap 25. The heat insulator 36 is provided to the furnace opening 15 so as to insulate the furnace opening 15 from heat. The motor 29 that rotates the boat 31 is located below the seal cap 25. The motor 29 is a hollow motor or has a structure in which a hollow shaft is motor-driven with a belt or the like. The rotary shaft 30 penetrates through the motor 29.

A heater unit 40 serving as a heater is disposed concentrically outside the process tube 11 and is supported by the casing 2. Thus, the heater unit 40 heats every substrate 1 retained in the substrate processing region of the boat 31. The heater unit 40 includes a case 41. The case 41 is made of stainless steel (SUS) and is tubular in shape with an upper end occluded and a lower end open, preferably, cylindrical in shape. The inner diameter and the full length of the case 41 are set larger than the outer diameter and the full length of the outer tube 12, respectively.

A heat insulating structure 42 is installed inside the case 41. The heat insulating structure 42 is tubular in shape, preferably, cylindrical in shape, and has a side wall 43 including a multilayered structure.

As illustrated in FIG. 1, a top wall 80 serving as a top covers the upper end side of the side wall 43 of the heat insulating structure 42 such that an inner space 75 is occluded. The top wall 80 is provided with an exhaust hole 81 that is annular in shape and serves as part of an exhaust path for exhausting the atmosphere in the inner space 75. The exhaust hole 81 has an upstream end serving as a lower end in communication with the inner space 75. The exhaust hole 81 has a downstream end connected to an exhaust duct 82. Then, cooling air supplied to the inner space 75 is exhausted through the exhaust hole 81 and the exhaust duct 82.

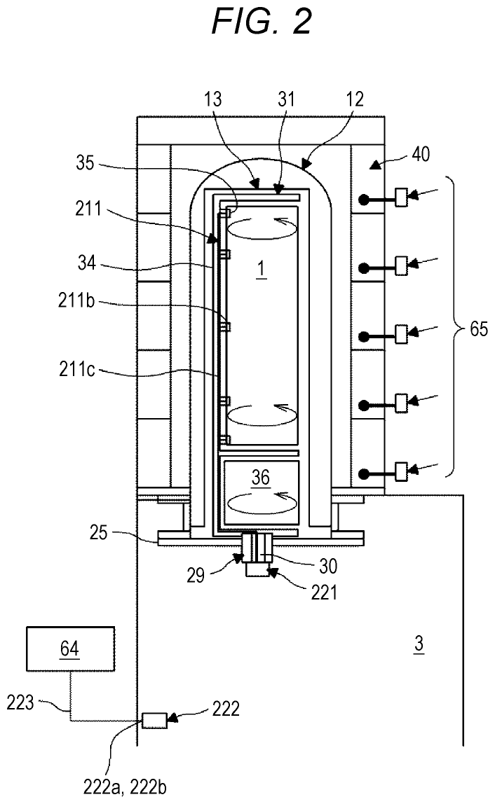

Next, the structure of the heater unit 40 will be described with FIG. 2. Referring to FIG. 2, substrates are not illustrated but are denoted with “1”. The heater unit 40 includes a plurality of heaters serving as a plurality of heat generators one-to-one in a plurality of zones in its longitudinal direction such that split control can be performed with the plurality of zones (referring to FIG. 2, 5-zone splitting), in which the plurality of heaters is stacked one on another. Then, a plurality of heater thermocouples 65 is installed one-to-one in the plurality of zones. Each heater thermocouple 65 measures the temperature of the corresponding heater.

Next, a temperature sensor 211 that measures the temperature of a substrate 1 will be described with FIG. 2. Based on rotation of the boat 31, the temperature sensor 211 rotates together with the substrates 1. The temperature sensor 211 includes a temperature detector 211b that measures the temperature of a substrate 1 and a cable 211c serving as an envelope that collectively envelops bodies (described later) that cover wires constituting the temperature detector 211b. Note that the temperature sensor 211 is not limited to a thermocouple and thus may be any sensor, such as a resistance thermometer, provided that temperature can be measured as an electric signal. The number of provided temperature detectors 211b is identical to, but not limited to, the number of zones of the heater unit 40. Preferably, the number of provided temperature detectors 211b is larger than the number of zones. In addition, preferably, temperature detector 211b has a height identical to the height of any of the heater thermocouples 65. Note that, needless to compare with heater thermocouple 65, temperature detector 211b is disposed close to a substrate 1. That is, temperature detector 211b is installed inside a support 35, and the cable 211c extends to the lower portion of the boat 31 through the inside of a prop 34 including a hollow in the boat 31. The cable 211c extending to the lower portion of the boat 31 is further laid, through a hole of the rotary shaft 30 fitting in a hole of the seal cap 25, in connection with a transmitter 221 below the seal cap 25. According to such a configuration, the cable 211c ranging to the transmitter 221 is disposed inside the boat 31 and is fully isolated from the process chamber 14 including a process space in which the substrates 1 are processed. Thus, the wires constituting temperature detector 211b inside the cable 211c are protected from disconnection due to rotation of the substrates 1 and the boat 31. The temperature sensor 211 is not exposed to the process chamber 14, so that the accuracy of temperature detection is retained.

As a structure, the transmitter 221 secured to the lower portion of the rotary shaft 30 is provided at the boundary between the process chamber 14 and the transfer chamber 3 adjacent to the process chamber 14 and moves together with the rotary shaft 30 and the substrates 1. As a structure, the rotary shaft 30 has a through hole through which the cable 211c passes. Under vacuum sealing with a hermetic seal, the cable 211c extends to the transmitter 221 outside the process chamber 14 (e.g., at the lower portion of the rotary shaft 30).

Then, the transmitter 221 digitally converts an electric signal (voltage) from each temperature detector 211b and transmits, by wireless, the digital signal through a radio wave.

A receiver 222 secured to the transfer chamber 3 that is an area below the seal cap 25 receives the signal from the transmitter 221 and then outputs the received digital signal in serial communication through a terminal (output terminal) 222a or converts the received digital signal into an analog signal, such as a 4-20 mA analog signal, and outputs the analog signal through a terminal (output terminal) 222b. The output signal terminal for the digital signal or the output signal terminal for the analog signal and a temperature display (not illustrated) or a temperature controller 64 are connected through a cable 223 in order to input temperature data into the temperature controller 64.

In the present embodiment, the temperature sensor 211, the transmitter 221, the receiver 222, and the temperature controller 64 achieve a temperature control system. According to such a configuration, provided is wireless transmission between the receiver 222 secured to the apparatus and a rotor including the temperature sensor 211, the boat 31, the rotary shaft 30, and the transmitter 221, namely, mechanical separation with a transmission path kept for temperature data. The temperature sensor 211, the boat 31, the rotary shaft 30, and the transmitter 221 included in the rotor rotate together, so that the cable 211c does not wind around the boat 31.

The signal output from the output terminal 222a or the output terminal 222b of the receiver 222 is input into the temperature controller 64, so that the temperature controller 64 displays the signal as temperature data. Temperature control to the heater unit 40 based on the temperature data input into the temperature controller 64 enables more accurate substrate temperature control, in comparison to conventional temperature control with a cascade thermocouple between the outer tube 12 and the inner tube 13.

Next, the operation in boat loading will be described. In order to load substrates 1 to the boat 31, the entirety of the boat 31 is located in the transfer chamber 3 and the transmitter 221 is located near the bottom of the transfer chamber 3. Note that the receiver 222 is secured to an inner wall near the bottom of the transfer chamber 3. After the substrates 1 are loaded to the boat 31, the boat elevator 26 (refer to FIG. 1) raises the boat 31 and the transmitter 221. The transmitter 221 rises from the lower portion toward the top of the transfer chamber 3 while moving away from the receiver 222. After that, the seal cap 25 is secured in contact with the manifold 16, so that the boat 31 is housed in the process chamber 14.

The transmitter 221 digitally converts the input electric signal (voltage) and transmits, to the receiver 222 secured to the inner wall of the transfer chamber 3 away from the transmitter 221, the digital signal by wireless through a radio wave. The receiver 222 is connected to the temperature controller 64 outside the transfer chamber 3 through the cable 223.

Due to wireless transmission of the temperature detected by the temperature sensor 211 built in the boat 31 from the transmitter 221 to the receiver 222, the temperature of the process chamber 14 can be controlled in real time. Although will be described in detail later, even in process, temperature control can be performed based on the temperature detected by the temperature sensor 211 close to the substrates 1, so that the temperature of every substrate 1 can be stabilized to the target temperature in a short time. Because of wireless transmission from the transmitter 221 to the receiver 222, no signal line (wire) is present in the transfer chamber 3. Therefore, for example, interference between a transferrer or the boat 31 and a signal line can be prevented and abnormality in data communication due to disconnection can be prevented. For example, even in a case where a temporary rise is made in temperature when the boat 31, on which the processed substrates 1 are mounted, is lowered to the transfer chamber 3, because of wireless transmission inside the transfer chamber 3, abnormality in data communication due to heat can be prevented.

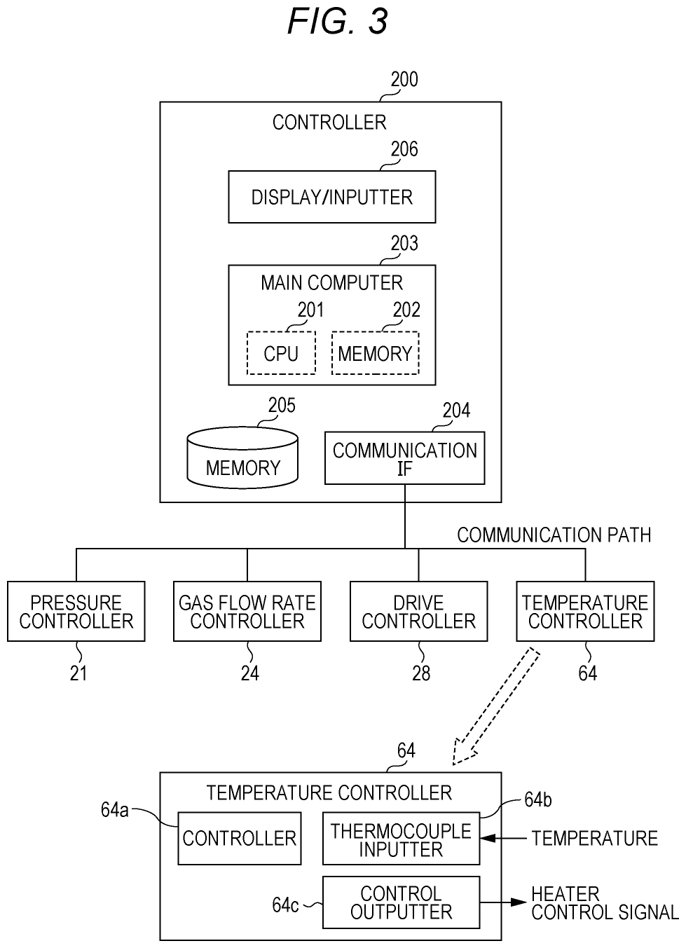

Next, a controller 200 that is a control computer serving as a controller will be described with FIG. 3. The controller 200 includes a main computer 203 including a central processing unit (CPU) 201 and a memory 202, a communication interface (IF) 204 serving as a communicator, a memory 205, and a display/inputter 206 serving as an operator. That is, the controller 200 includes constituents for a general computer.

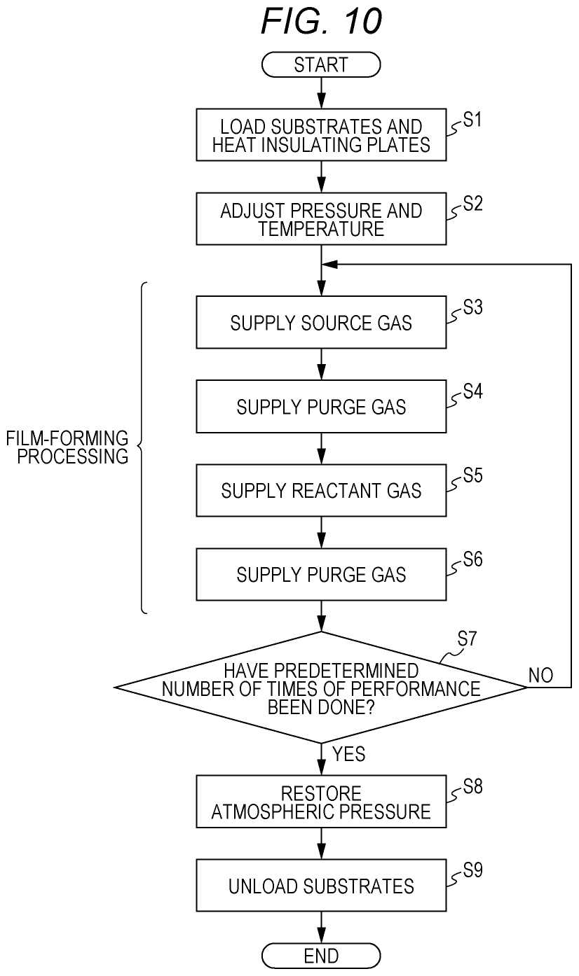

The CPU 201 serving as an operational core executes a control program stored in the memory 205 and executes a recipe recorded in the memory 205 (e.g., a process recipe) in accordance with an instruction from the display/inputter 206. Note that, needless to say, the process recipe includes temperature control from step S1 to step S9, described later, illustrated in FIG. 10.

The memory 202 serving as a temporary memory functions as a work area for the CPU 201.

The communication IF 204 is electrically connected to the pressure controller 21, the gas flow rate controller 24, the drive controller 28, and the temperature controller 64 (also collectively referred to as a sub-controller). The controller 200 can exchange data regarding the operation of each component with the sub-controller through the communication IF 204. The temperature controller 64 includes a controller 64a, a thermocouple inputter 64b to which temperature information is input from the heater thermocouples 65 and the temperature sensor 211, and a control output 64c that outputs a control signal to the heater unit 40.

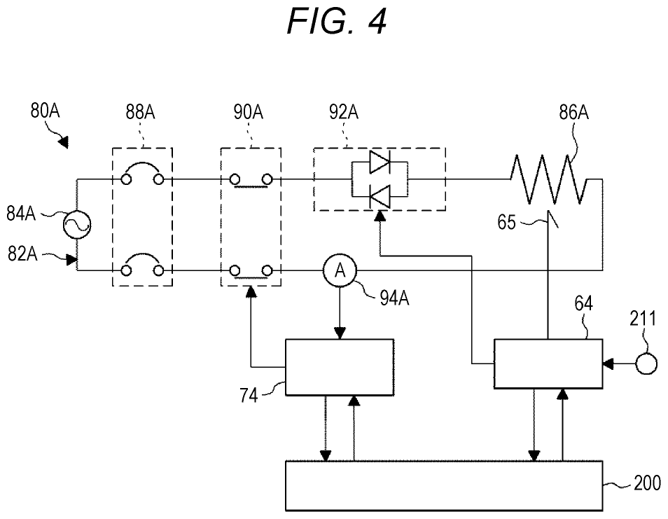

Next, control of heat generation of the heater unit 40 will be described with FIG. 4. FIG. 4 illustrates a heater drive 80A to any one of the plurality of zones illustrated in FIG. 2. The heater drive 80A includes a drive circuit 82A. The drive circuit 82A includes a power source 84A, a heater wire 86A, a breaker 88A, a contactor 90A, a thyristor 92A serving as a power supplier, and an ammeter 94A serving as a measurer.

The power source 84A supplies the drive circuit 82A with power for use in the heater wire 86A. In the present embodiment, the power source 84A is an alternating-current power source. Note that, in the present embodiment, a power source is connected per drive circuit, but the present disclosure is not limited to this configuration. For example, a single power source may be used for a plurality of drive circuits.

The heater wire 86A is a member that generates heat in response to supply of power. The heater serving as a heat generator in each zone of the heater unit 40 is achieved with such a heater wire 86A.

The breaker 88A is disposed between the power source 84A and the heater wire 86A in the drive circuit 82A. The breaker 88A is a device that stops a fault current that flows in response to occurrence of trouble or abnormality in the drive circuit 82A.

The contactor 90A is disposed between the breaker 88A and the heater wire 86A in the drive circuit 82A. The contactor 90A is a device that makes or breaks the drive circuit 82A. An abnormality detection controller 74 controls the contactor 90A to make or break the drive circuit 82A.

The thyristor 92A is disposed between the contactor 90A and the heater wire 86A in the drive circuit 82A. The thyristor 92A is a device that controls the power supplied from the power source 84A to the heater wire 86A. The thyristor 92A is switching-controlled (on/off-controlled), based on a signal output from the control output 64c of the temperature controller 64.

The ammeter 94A is disposed between the contactor 90A and the heater wire 86A in the drive circuit 82A. The ammeter 94A is an instrument that measures a current flowing in the drive circuit 82A. The measurement value of the current measured by the ammeter 94A is transmitted to the abnormality detection controller 74.

A heater thermocouple 65 is disposed near the heater wire 86A. The temperature detected by the heater thermocouple 65 is transmitted to the thermocouple inputter 64bof the temperature controller 64. Similarly, the temperature detected by the temperature sensor 211 is transmitted to the thermocouple inputter 64b of the temperature controller 64. Then, with at least one of the temperature detected by the heater thermocouple 65 and the temperature detected by the temperature sensor 211, the controller 64aexecutes a temperature control program set in advance to the temperature controller 64. A result of the execution is output to the thyristor 92A.

In particular, considering a reduction in process temperature in future, mainly with the temperature detected by the temperature sensor 211, the controller 64a executes the temperature control program set in advance to the temperature controller 64. A result of the execution is output to the thyristor 92A. The reason is as follows. Even if the temperature of the heater thermocouple 65 is measured, since the heater thermocouple 65 is away from the substrates 1, it can be easily estimated that temperature control is difficult to perform in response to a minute change in temperature. Meanwhile, since the temperature sensor 211 is provided inside a support 35 and is disposed near the end portion of a substrate 1, it can be thought that a minute change in temperature can be detected.

The controller 200 controls the temperature controller 64 and the abnormality detection controller 74.

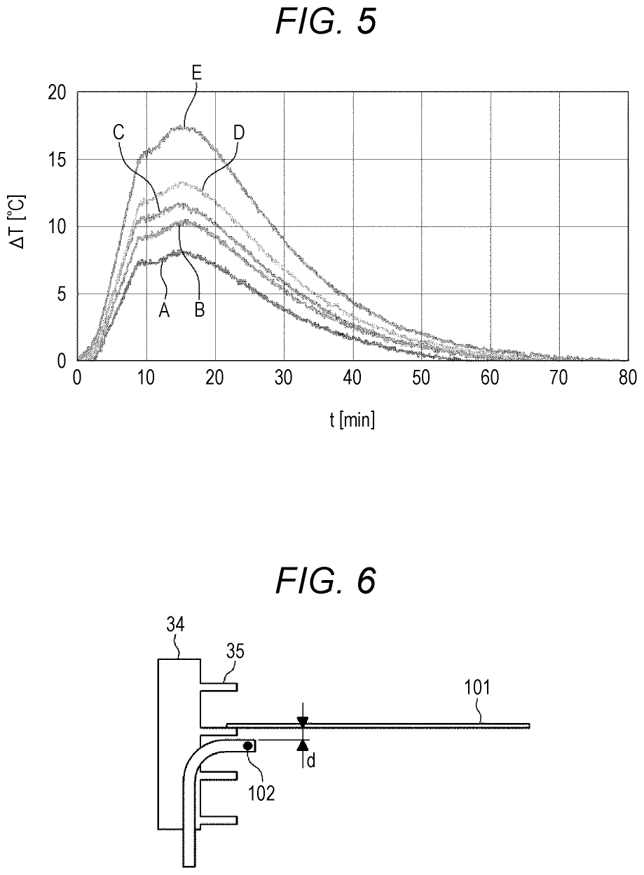

Next, a boat assembly serving as a substrate supporter including a boat 31 and a temperature sensor 211 will be described. Results from preparatory experiments for a better understanding of a temperature sensor provided in a boat assembly and measurement of the temperature of a wafer in the present embodiment will be described with FIGS. 5 and 6.

As illustrated in FIG. 6, a support 35 provided at a prop 34 of a boat 31 retains a thermocouple-equipped wafer 101, and a thermocouple 102 is installed at the prop 34 near the thermocouple-equipped wafer 101. For example, every time the thermocouple-equipped wafer 101 is heated to 200° C., a change is made in the distance (d) between the thermocouple-equipped wafer 101 and the thermocouple 102, and temperature measurement is performed with a thermocouple with which the thermocouple-equipped wafer 101 is provided and the thermocouple 102. FIG. 5 is a graph indicating the relationship between the temperature difference (ΔT [° C.]) between the thermocouple with which the thermocouple-equipped wafer 101 is provided and the thermocouple 102 and elapsed time (t [min]). As the distance (d), 0 mm (A), 0.005 mm (B), 0.1 mm (C), 0.3 mm (D), and 1 mm (E) are selected. As indicated in FIG. 5, a smaller distance (d) causes a less temperature difference. At the time of contact (d=0 mm), the temperature difference is minimum. This is because heat travels efficiently due to thermal conduction.

As above, it is found that, for an accurate detection result of temperature with the thermocouple, the thermocouple in contact with the measurement target (wafer 101) is the most effective. Note that the method of measuring temperature illustrated in FIG. 6 requires that the thermocouple and the measurement target are disposed in the same space. Thus, in practical substrate processing, it can be thought that the thermocouple disposed near the measurement target affects a flow of gas on the surface of the measurement target. The thermocouple is identical in processing conditions, such as processing gas and temperature, to the measurement target. Thus, the thermocouple needs a high thermal resistance. In addition, metallic contamination is likely to occur due to the thermocouple.

In general, before processing, temperature is detected with the thermocouple-equipped wafer 101. Then, based on a result of the detection, in substrate processing, temperature control is performed with another thermocouple, for example, freely with a correction value. For a reduction in process temperature in future, required is a technique enabling temperature measurement in substrate processing with a thermocouple disposed as close to a measurement target as possible and with inhibition of disturbance.

Thus, the boat (hereinafter, also referred to as a boat assembly) 31 in the present embodiment enables more accurate measurement of the temperature of a substrate 1 because the temperature sensor 211 has a temperature detector 211b built inside a support 35 that is a part for contact with the substrate 1 in order to support the substrate 1.

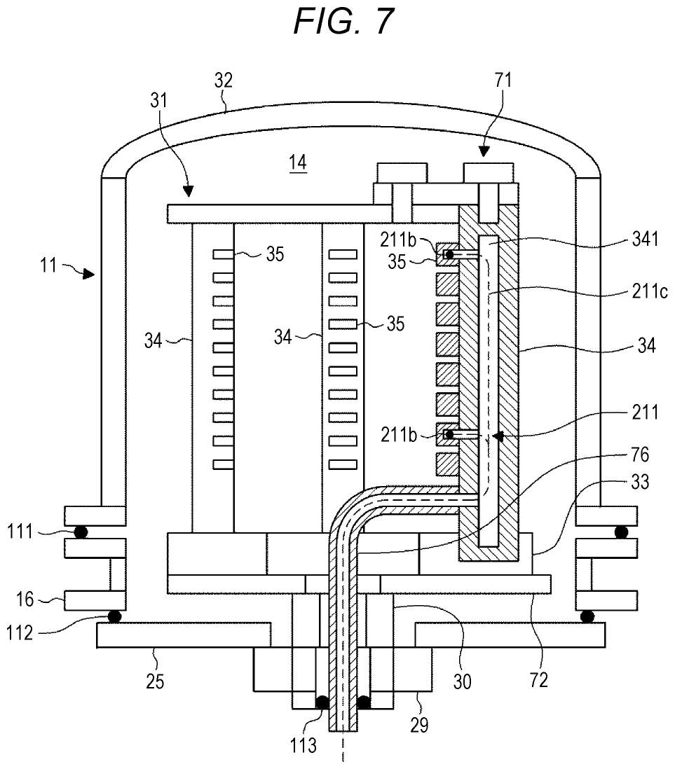

The boat assembly in the present embodiment will be described with FIGS. 7 and 10. As described above, the temperature sensor 211 includes a temperature detector 211b that measures the temperature of a substrate 1 and a cable 211c that collectively envelops bodies (described later) that cover wires included in the temperature detector 211b. As illustrated in FIG. 7, the cable 211c extends to the lower portion of the boat 31 through a prop 34 including a space (first space) 341 inside from among the plurality of props 34 of the boat 31. The cable 211c extending to the lower portion of the boat 31 is further stored and guided inside an L-shaped pipe 76 as a cylindrical portion connected below (lower than) the lowermost support 35 of the prop 34. As above, since the cable 211c, which extends from the temperature detector 211b and is isolated from the process space, is attached to the boat 31 in a unified manner, even when the boat 31 rotates, the cable 211c is not disconnected, so that reliable temperature measurement can be performed. The space 341 provided with the temperature sensor 211 and the process chamber 14 are isolated by the prop 34 and the pipe 76, and thus the temperature sensor 211 can be prevented from being affected by processing gas. Therefore, the temperature of the substrate 1 can be measured accurately. Furthermore, metallic contamination due to the temperature sensor 211 can be inhibited to the substrate 1.

At the time of processing of substrates 1, the seal cap 25 supports the process tube 11 through the manifold 16 and O rings 111 and 112 to seal the process chamber 14. The seal cap 25 has a hole at its center, and a boat bearing 72 penetrates through the hole. The boat bearing 72 is sealed with an O ring 113, so that a rotational operation can be performed by the motor 29 with the furnace kept vacuous.

As a structure, the pipe 76 containing the cable 211c protrudes below the seal cap 25 through the hole at the center of the boat bearing 72. The pipe 76 protruding below the seal cap 25 is secured to the boat bearing 72 with a securing method enabling vacuum sealing.

The end plate 33 that is the lower end portion of the boat 31 is installed on the boat bearing 72. As a structure, the pipe 76 protruding from the center of the boat bearing 72 to the process chamber 14 extends laterally and is connected to the prop 34 including the space 341 inside.

The end plate 33 that is the bottom plate of the boat 31 is provided with a recess for erecting the prop 34 including the space 341 inside. The prop 34 including the space 341 inside has an upper portion provided with a recess enabling securing of the prop 34 including the space 341 inside. The prop 34 including the space 341 inside is secured, by a fastener 71, to the end plate 32 that is the top plate of the boat 31. The recess at the upper portion of the prop 34 enables isolation of the space 341 from the process chamber 14. As above, the prop 34 including the space 341 in which the temperature sensor 211 is built is separate from the body of the boat 31 and thus is assembled on the seal cap 25 as a structure.

According to such a structure, the prop 34 including the space 341 inside is secured to the boat 31 such that, between the prop 34 including the space 341 inside and the props 34 including no space 341 inside, the width (pitch) between each support 35 is uniform in top view and the heights of the corresponding supports 35 are identical in side view.

As described above, the support 35 including the temperature detector 211bdisposed inside is separate from the boat 31 and is replaceable. Thus, in order to make the support 35 including the temperature detector 211b disposed inside identical to the other supports in terms of influence to the substrate 1 being supported, the support 35 including the temperature detector 211b disposed inside can be freely made different in configuration from the supports 35 including no temperature detector 211b disposed inside. For example, the support 35 including the temperature detector 211b disposed inside may be different in material from the supports 35 including no temperature detector 211b disposed inside such that heat conducted to the support 35 including the temperature detector 211b disposed inside is equivalent to heat conducted to the supports 35 including no temperature detector 211b disposed inside. The support 35 including the temperature detector 211b disposed inside is not necessarily different in external appearance from the supports 35 including no temperature detector 211b disposed inside. That is, the support 35 including the temperature detector 211b disposed inside may be identical in external appearance to the supports 35 including no temperature detector 211b disposed inside. Note that, in the present specification, the space that the support 35 has inside is referred to as a second space in distinction from the space 341 that the prop 34 has inside. The second space will be described in detail later.

The boat 31 including the temperature sensor 211 is mounted on the boat bearing 72 as a structure. In response to rotation of the boat bearing 72 by the motor 29, the boat 31 rotates together with the boat bearing 72. Note that the seal cap 25 does not rotate. Since the temperature sensor 211 is attached to the boat 31 in a unified manner, even when the boat 31 rotates, the temperature sensor 211 can perform reliable temperature measurement.

The cable 211c extending below the seal cap 25 is connected to the transmitter 221 that rotates together with the boat bearing 72, enabling substrate temperature measurement with the substrates 1 rotating.

As described above, the heater unit 40 that heats the substrates 1 is split-controlled with a plurality of zones. This is because control is performed for uniform temperature to a plurality of substrates 1 mounted on the boat 31. Therefore, a heater thermocouple 65 for control is provided per zone. Preferably, the number of temperature detectors 211b to be installed in the boat 31 is identical to the number of heater thermocouples 65.

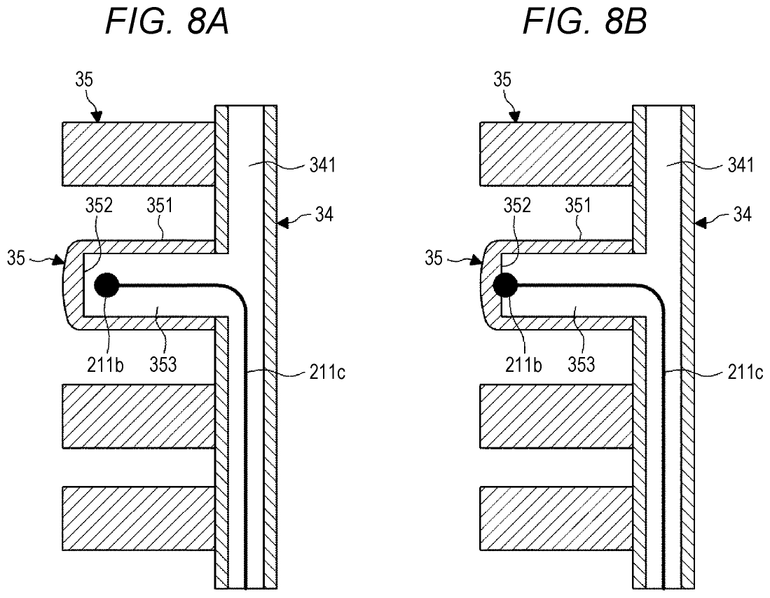

The positional relationship between a support 35 and a temperature detector 211bwill be described with FIGS. 8A and 8B. A temperature detector 211b is built inside a support 35 to have contact with the end portion of a substrate 1 in the boat 31. In other words, the support 35 has a wall as a boundary such that the process space and the space in which the temperature detector 211b is installed are isolated. A prop 34 is provided with a plurality of supports 35. At least one of the supports 35 has a first face 351 serving as an outer wall that supports a substrate 1 in contact, a space (second space) 353 in which a temperature detector 211b is installed, and a second face 352 serving as an inner wall facing the space 353. That is, the first face 351 faces the process chamber 14 including the process space in which the substrate 1 is processed, and the second face 352 faces the space 353 isolated from the process chamber 14. Since the temperature detector 211b is provided inside the support 35 that supports the substrate 1, so that the temperature sensor is close to the wafer even in process, leading to accurate measurement of the temperature of the wafer. The temperature detector 211b is disposed such that the temperature of the end portion (rim) of the substrate 1 can be measured. Thus, the temperature of the end portion (rim) of the substrate 1 can be accurately measured, the end portion (rim) of the substrate 1 being higher in the followability to a variation in temperature (e.g., a rise in temperature or a drop in temperature) than the center of the substrate 1. Then, the temperature detected by the temperature detector 211b disposed highly close to the substrate 1 is controlled, so that inhibition of an overshoot at a rise in temperature can be achieved.

Preferably, as illustrated in FIG. 8A, the temperature detector 211b is secured close to the second face 352 of the support 35. More preferably, as illustrated in FIG. 8B, the temperature detector 211b is disposed in contact with the second face 352 of the support 35. The temperature detector 211b in contact with the support 35 is preferable in thermal conduction, leading to more accurate temperature measurement. Note that, even in a case where the temperature detector 211b is out of contact with the support 35, adjustment is performed in consideration of a large error. According to such configurations, the temperature detector 211b is close to the substrate 1 mounted on the support 35, so that the temperature of the substrate 1 can be accurately measured.

Note that, referring to FIG. 8B, the temperature detector 211b is in contact with the second face 352 of the side wall of the support 35. Preferably, the temperature detector 211b is in contact with the second face 352 on the upper side on which the substrate 1 is mounted. That is, in terms of temperature control, the temperature detector 211b is preferably in contact with a face closer to the substrate 1. The thickness of the second face 352 is set such that the support 35 is identical in terms of influence to the substrate 1 being supported to any support 35 in which no temperature detector 211b is disposed. Furthermore, the wall of the support 35 may have a face that supports the substrate 1, a side face, and a lower face that are identical or different in thickness.

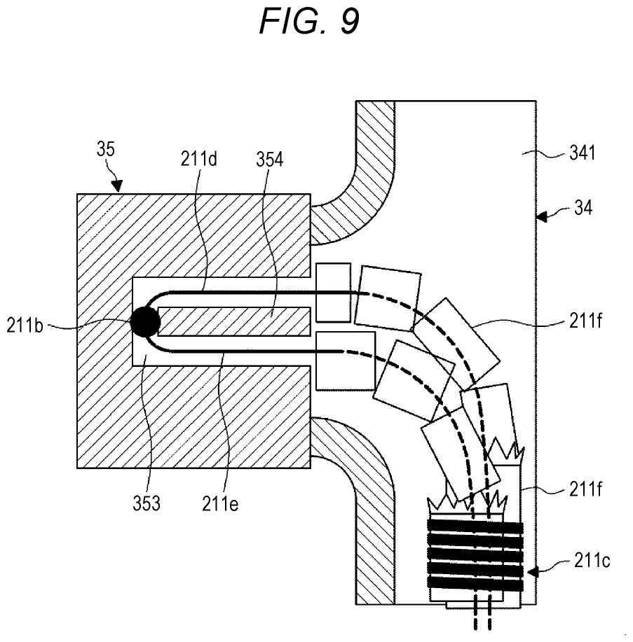

A detailed structure of the temperature sensor 211 will be described with FIG. 9. A thermocouple per temperature detector 211b includes two wires 211d and 211e requiring mutual insulation. Thus, the wires 211d and 211e are each covered with a jacket 211f serving as a body. The wires 211d and 211e are each insulated with an insulating tube, such as a quartz narrow tube, a ceramic tube, or an alumina sleeve, serving as the jacket 211f. The cable 211c serves as an envelope that collectively envelops such jackets 211f. The bodies 211f enveloped by the cable 211c are provided at least in the space 341 of the prop 34. Referring to FIG. 9, each body 211f has a plurality of divisions such that bending is achieved from the inside of the prop 34 to the inside of the support 35. The temperature detector 211b is extracted from the bodies 211f near the support 35. The cable 211c is provided with a plurality of such temperature detectors 211b. Thus, the temperature sensor 211 (temperature detector 211b) can be provided inside such a support 35, that is, the temperature sensor 211 (temperature detector 211b) is close to the wafer even in process, leading to accurate measurement of the temperature of the wafer. Note that an insulator 354 disposed between the wire 211d and the wire 211e illustrated in FIG. 9 is tabular in shape, but this is not limiting. Provided that the wire 211d and the wire 211e can be insulated, any configuration may be adopted. For example, inside the support 35 (in the second space 353), an alumina sleeve serving as the envelope 211c may be wound around each of the wires 211d and 211e with no body 211f.

In the embodiment described above, the temperature sensor 211 including a plurality of temperature detectors 211b is provided to one prop as an example. However, temperature detectors 211b may be disposed in a plurality of props in a distributing manner.

The temperature sensor 211 is built in at least one of the plurality of props of the boat 31 that supports substrates 1. In a case where the temperature sensor 211 is built in the plurality of props, the temperatures at a plurality of places on a circumference can be measured. Typically, the temperature of the edge of a substrate 1 varies circumferentially. In an apparatus including no boat rotator, measurement of the temperature at a single place corresponds to measurement of a temperature deviating from the average temperature of the wafer. However, in a case where the temperatures measured by the temperature sensor 211 attached to every prop are averaged, a temperature closer to the average temperature of the wafer can be measured.

In the above description, temperature information on every temperature detector 211b based on the process chamber 14 is transmitted by wireless as an example. However, such temperature information may be transmitted by a slip ring.

Next, an exemplary sequence of processing of forming a film on a substrate (hereinafter, also referred to as film-forming processing) as a partial process in a process of manufacturing a semiconductor device, with the substrate processing apparatus 10 described above will be described with FIG. 10.

Exemplary formation of a silicon film onto a substrate 1 with source gas and reactant gas will be described below. Note that, in the following description, the operation of each constituent in the substrate processing apparatus 10 is controlled by the controller 200 and the sub-controller.

In film-forming processing in the present embodiment, a process in which a step of supplying source gas to substrates 1 in the process chamber 14, a step of removing source gas (residual gas) from the process chamber 14, a step of supplying reactant gas to the substrates 1 in the process chamber 14, and a step of removing reactant gas (residual gas) from the process chamber 14 are performed asynchronously is performed a predetermined number of times (one or more times) to form a film on each substrate 1.

### Substrate Loading: Step S1

The drive controller 28 operates the transferrer and a transferrer elevator such that a plurality of substrates 1 is charged and retained in the substrate processing region of the boat 31 (wafer charge). Note that a plurality of heat insulating plates 120 is charged and retained in advance in the heat-insulating-plate region of the boat 31.

Then, the drive controller 28 operates the boat elevator 26 to insert the boat 31, in which the substrates 1 and the heat insulating plates 120 are retained, into the process tube 11, so that the boat 31 is loaded in the process chamber 14 (boat loading). In this case, the seal cap 25 has airtightly occluded (sealed) the lower end of the process tube 11 through the O ring 112 (refer to FIG. 7).

### Pressure Adjustment and Temperature Adjustment: Step S2

The pressure controller 21 controls the exhaust 19 such that the process chamber 14 is at a predetermined pressure (predetermined degree of vacuum). In this case, the pressure sensor 20 measures the pressure of the process chamber 14. Then, based on pressure information resulting from the measurement, the exhaust 19 is feedback-controlled. The exhaust 19 keeps operating at least until termination of processing to the substrates 1.

The heater unit 40 performs heating such that the substrates 1 in the process chamber 14 are at a predetermined temperature. In this case, based on temperature information detected by at least one of every heater thermocouple 65 and the temperature sensor 211, the temperature controller 64 feedback-controls the degree of energization to the heater unit 40 such that the process chamber 14 has a predetermined temperature distribution. The heater unit 40 keeps heating the process chamber 14 at least until termination of processing to the substrates 1.

In addition, the motor 29 starts to rotate the boat 31 and the substrates 1. Specifically, when the motor 29 rotates due to the drive controller 28, the boat 31 and the transmitter 221 rotate together with the substrates 1. The rotation of the boat 31, the transmitter 221, and the substrates 1 due to the rotation of the motor 29 is kept at least until termination of processing to the substrates 1.

### Film-Forming Processing

When the temperature inside the process chamber 14 stabilizes to a previously set processing temperature, the following four steps, namely, steps S3 to S6 are performed in order.

### Source Gas Supply: Step S3

In this step, source gas is supplied to the substrates 1 in the process chamber 14.

In this step, the source gas introduced from the gas introducing pipe 22 to the process chamber 14 is controlled in flow rate by the gas flow rate controller 24 and then flows through the process chamber 14 of the inner tube 13. Then, the source gas passes through the exhaust path 17 and then is exhausted through the exhaust pipe 18. In this case, simultaneously, N₂ gas flows into the gas introducing pipe 22. The N₂ gas is adjusted in flow rate by the gas flow rate controller 24. Then, the N₂ gas is supplied together with the source gas to the process chamber 14 and then is exhausted through the exhaust pipe 18. Due to the supply of the source gas to the substrates 1, as a first layer, for example, a layer of a thickness ranging approximately from a monolayer to a few atomic layers is formed on the outermost face of each substrate 1.

### Purge Gas Supply: Step S4

After formation of the first layer, the supply of the source gas is stopped. In this case, the exhaust 19 vacuum-exhausts the process chamber 14 to discharge, from the process chamber 14, the residual unreacted source gas or the residual source gas after contributing to the formation of the first layer in the process chamber 14. In this case, the supply of the N₂ gas to the process chamber 14 is kept. The N₂ gas acts as purge gas, leading to an enhancement in the effect of discharging, from the process chamber 14, the residual gas in the process chamber 14.

### Reactant Gas Supply: Step S5

After step S4, reactant gas is supplied to the substrates 1 in the process chamber 14, namely, the first layer formed on each substrate 1. The reactant gas is activated by heat and is supplied to the substrates 1.

In this step, the reactant gas introduced from the gas introducing pipe 22 to the process chamber 14 is controlled in flow rate by the gas flow rate controller 24 and then flows through the process chamber 14 of the inner tube 13. Then, the reactant gas passes through the exhaust path 17 and then is exhausted through the exhaust pipe 18. In this case, simultaneously, N₂ gas flows into the gas introducing pipe 22. The N₂ gas is adjusted in flow rate by the gas flow rate controller 24. Then, the N₂ gas is supplied together with the reactant gas to the process chamber 14 and then is exhausted through the exhaust pipe 18. In this case, the reactant gas is supplied to the substrates 1. The reactant gas supplied to the substrates 1 reacts with at least part of the first layer formed on each substrate 1 in step S3. Thus, the first layer is nitrided in non-thermal plasma to change to a second layer.

### Purge Gas Supply: Step S6

After formation of the second layer, the supply of the reactant gas is stopped. Then, in accordance with a processing procedure similar to that in step S4, the residual unreacted reactant gas, the residual reactant gas after contributing to the formation of the second layer, or any reaction byproduct in the process chamber 14 is discharged from the process chamber 14. In this case, for example, the residual gas in the process chamber 14 is not necessarily completely discharged, similarly to step S4.

### Predetermined Number of Times of Performance: Step S7

A process in which the four steps described above are performed asynchronously, namely, out of synchronization is performed a predetermined number of times (n number of times), so that a film of a predetermined thickness can be formed on each substrate 1. Note that, preferably, the thickness of a second layer formed every time the process described above is performed is smaller than a predetermined thickness, and the process described above is performed a plurality of times such that a film formed based on a stack of second layers has the predetermined thickness.

### Purge and Atmospheric Pressure Restoration: Step S8

After completion of the film-forming processing, N₂ gas is supplied from the gas introducing pipe 22 to the process chamber 14 and then is exhausted through the exhaust pipe 18. The N₂ gas acts as purge gas. Thus, the process chamber 14 is purged, so that the residual gas or any reaction byproduct is removed from the process chamber 14 (purge). Simultaneously, in order to efficiently reduce the temperature of the process chamber 14 from the processing temperature, cooling air flows into the inner space 75 to cool the process tube 11. In this case, based on the temperature detected by the temperature sensor 211, the temperature controller 64 may control the cooling of the process chamber 14 by the cooling air or the temperature controller 64 may determine whether to stop the cooling. After that, the atmosphere in the process chamber 14 is replaced with inert gas (inert gas replacement), so that the pressure of the process chamber 14 is restored to normal pressure (atmospheric pressure restoration). In this case, based on the temperature detected by the temperature sensor 211, the temperature controller 64 may determine whether to allow a transition to boat unloading as the next step.

### Substrate Unloading: Step S9

The drive controller 28 lowers the boat elevator 26 to lower the seal cap 25, so that the lower end of the process tube 11 is open. Then, the processed substrates 1 supported by the boat 31 are unloaded outward from the process tube 11 through the lower end of the process tube 11 (boat unloading). The processed substrates 1 are discharged from the boat 31 (wafer discharge).

### (3) Effects According to Present Embodiment

According to the present embodiment, one or a plurality of effects below can be obtained.
(a) The temperature sensor is close to a wafer even in process, so that the temperature of the wafer can be accurately detected.
(b) The temperature of the end portion of the wafer can be detected, the end portion of the wafer being higher in the followability to a variation in temperature (e.g., a rise in temperature or a drop in temperature) than the center of the wafer.
(c) The temperature detected by the temperature sensor built in the boat (temperature of the end portion of the wafer) is controlled, so that an overshoot can be inhibited at a rise in temperature and temperature stabilization can be achieved at a drop in temperature.
(d) Temperature control can be performed with the temperature sensor close to the wafer even in process, so that the temperature of the wafer can be stabilized to the target temperature in a short time.
(e) Influence to process temperature can be more accurately grasped, so that the temperature of the wafer in heat treatment can be more accurately controlled, leading to an improvement in the accuracy of process control.
(f) In a low temperature domain, the temperature of the wafer can be controlled more accurately and more promptly. Thus, a reduction can be achieved in the time required for temperature recovery at the time of the boat up or at a rise or drop in temperature. Thus, an improvement can be made in throughput and a reduction can be made in processing energy per wafer (energy saving).

The embodiment of the present disclosure has been specifically described above. However, the present disclosure is not limited to the embodiment described above, and thus various modifications can be made without departing from the gist of the present disclosure.

Each support of the boat may be, as a configuration, a groove (support) engraved on a prop as before such that a substrate can be mounted. Each support that supports the end portion of a substrate is not limited in shape and thus may be an annular support (e.g., a C-ring support) attached to a groove.

In the embodiment described above, exemplary film forming has been given and is not particularly limited to the type of a film to be formed. For example, the film forming can be applied to various types of films, such as an oxide film, specifically, a silicon oxide film (SiO film) or a metal oxide film.

The film-forming processing include, for example, chemical vapor deposition (CVD), physical vapor deposition (PVD), processing of forming an oxide film, a nitride film, or both thereof, or processing of forming a film containing metal. In addition, processing such as annealing, oxidizing, nitriding, or diffusing may be included.

In the embodiment described above, the substrate processing apparatus has been given. The substrate processing apparatus can be applied to a general semiconductor manufacturing apparatus. In addition to such a semiconductor manufacturing apparatus, the substrate processing apparatus can be applied to an apparatus that processes a glass substrate for a liquid crystal display (LCD) device.

According to an embodiment of the present disclosure, in processing a substrate, a temperature sensor can be made close to the substrate.

What is claimed is:

1. A substrate supporter comprising:
a plurality of supports configured to support a substrate;
at least one upright including a first space inside; and
a temperature sensor provided in the first space, the temperature sensor including a temperature detector configured to measure a temperature of the substrate, wherein
at least one support of the plurality of supports includes a second space inside in communication with the first space to allow the temperature detector to be installed in the second space.

2. The substrate supporter according to claim 1, wherein the temperature detector is disposed so as to measure a temperature of an end portion of the substrate.

3. The substrate supporter according to claim 1, wherein the at least one support includes a first face configured to support the substrate and a second face facing the second space.

4. The substrate supporter according to claim 3, wherein the first face faces a process space in which the substrate is processed, and the second face faces the second space isolated from the process space.

5. The substrate supporter according to claim 3, wherein the temperature detector is disposed close to the second face of the at least one support.

6. The substrate supporter according to claim 1, wherein the at least one support is configured to be replaceable depending on whether the temperature detector is installed inside.

7. The substrate supporter according to claim 1, wherein the plurality of supports is arranged along a parallel direction to the at least one upright, and
a width between each of the plurality of supports is constant without depending on whether or not the temperature detector is disposed inside.

8. The substrate supporter according to claim 1, wherein the temperature sensor further includes a body that covers a wire constituting the temperature detector at least inside the at least one upright, and
the body is provided to be divided into a plurality of parts to allow bending from the at least one upright to the at least one support.

9. The substrate supporter according to claim 1, wherein the temperature sensor further includes a body that covers a wire constituting the temperature detector at least inside the at least one upright, and
the wire covered by the temperature detector is pull out from the body near the at least one support.

10. The substrate supporter according to claim 9, wherein a plurality of temperature detectors including the temperature detector are provided with the body.

11. The substrate supporter according to claim 1, wherein the temperature sensor is provided to each of a plurality of uprights including the at least one upright.

12. A substrate processing apparatus comprising a substrate supporter including:
a plurality of supports configured to support a substrate;
at least one upright including a first space inside; and
a temperature sensor provided in the first space, the temperature sensor including a temperature detector configured to measure a temperature of the substrate, wherein
at least one support of the plurality of supports includes a second space inside in communication with the first space to allow the temperature detector to be installed in the second space.

13. The substrate processing apparatus according to claim 12, further comprising a rotator configured to rotate the substrate supporter,
wherein the rotator is configured to rotate the substrate together with the substrate supporter.

14. The substrate processing apparatus according to claim 12,
wherein the temperature sensor includes: a body that covers a wire constituting the temperature detector; and an envelope enveloping the body, and
a cylindrical portion that guides the envelope is provided at a lower end portion of the substrate supporter.

15. The substrate processing apparatus according to claim 13, further comprising a transmitter provided at a lower portion of the rotator, the transmitter being configured to rotate together with the substrate, wherein the transmitter is configured to convert an input signal digitally.

16. The substrate processing apparatus according to claim 15, further comprising:
a receiver configured to receive a signal output from the transmitter; and
a controller connected to the receiver,
where the receiver is configured to receive a digital signal output from the transmitter to the receiver by wireless, convert the digital signal received into an analog signal, and output the analog signal to the controller.

17. The substrate processing apparatus according to claim 16, further comprising:
a process chamber; and
a transfer chamber adjacent to the process chamber, wherein the receiver is provided on an inner wall of the transfer chamber away from the transmitter provided at a boundary between the process chamber and the transfer chamber.

18. A method of manufacturing a semiconductor device, comprising:
Supporting a substrate by a substrate supporter including: a plurality of supports configured to support the substrate; at least one upright including a first space inside; and a temperature sensor provided in the first space, the temperature sensor including a temperature detector configured to measure a temperature of the substrate, wherein at least one support of the plurality of supports includes a second space in communication with the first space inside to allow the temperature detector to be installed in the second space; and
processing the substrate with controlling a temperature of a process space in which the substrate is present based on the temperature detected by the temperature sensor.

19. A non-transitory computer-readable recording medium storing a program that causes, by a computer, a substrate processing apparatus to perform:
detecting a temperature by the temperature sensor in a substrate supporter, the substrate supporter comprising:
a plurality of supports configured to support a substrate;
at least one upright including a first space inside; and
a temperature sensor provided in the first space, the temperature sensor including a temperature detector configured to measure a temperature of the substrate, wherein at least one support of the plurality of supports includes a second space inside in communication with the first space to allow the temperature detector to be installed in the second space.; and
processing the substrate with controlling a temperature of a process space in which the substrate is present based on the temperature detected by the temperature sensor.
